(19) United States
(12) Patent Application Publication
(10) Pub. No.: US 2008/0173985 A1
(43) Pub. Date: Jul. 24, 2008

(54) DIELECTRIC CAP HAVING MATERIAL WITH OPTICAL BAND GAP TO SUBSTANTIALLY BLOCK UV RADIATION DURING CURING TREATMENT, AND RELATED METHODS

(75) Inventors: Michael P. Belyansky, Bethel, CT (US); Griselda Bonilla, Fishkill, NY (US); Xiao Hu Liu, Briarcliff Manor, NY (US); Son Van Nguyen, Yorktown Heights, NY (US); Thomas M. Shaw, Peekskill, NY (US); Hosadurga K. Shobha, Yorktown Heights, NY (US); Daewon Yang, Hopewell Junction, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/626,552

(22) Filed: Jan. 24, 2007

(51) Int. Cl. H01L 23/58; H01L 21/318

(52) U.S. Cl. 257/649; 438/792; 257/E21.293; 257/E23.002

(57) ABSTRACT

A dielectric cap and related methods are disclosed. In one embodiment, the dielectric cap includes a dielectric material having an optical band gap (e.g. greater than about 3.0 electron-Volts) to substantially block ultraviolet radiation during a curing treatment, and including nitrogen with electron donor, double bond electrons. The dielectric cap exhibits a high modulus and is stable under post ULK UV curing treatments for, for example: copper low k back-end-of-line (BEOL) nanoelectronic devices, leading to less film and device cracking and improved reliability,

### BACKGROUND OF THE INVENTION

1. Technical Field

The invention relates generally to integrated circuit (IC) chip fabrication, and more particularly, to a dielectric cap for ultra low dielectric constant (ULK) inter-level dielectrics.

2. Background Art

In traditional IC chips, aluminum and aluminum alloys have been used as interconnect metallurgies for providing electrical connections to and from devices in back-end-of-line (BEOL) layers of the devices. While aluminum-based metallurgies have been the material of choice for use as metal interconnects in the past, aluminum no longer satisfies the requirements as circuit density and speeds for IC chips increase and the scale of devices decreases to nanometer dimensions. Thus, copper is being employed as a replacement for aluminum because of its lower resistivity and its lower susceptibility to electromigration failure as compared to aluminum.

One challenge relative to using copper is that it diffuses readily into the surrounding dielectric material as processing steps continue. To inhibit the copper diffusion, copper interconnects can be isolated by employing protective barrier layers. Such barrier layers include, for example, conductive diffusion barrier liners of tantalum, titanium or tungsten, in nearly pure or alloy form, along the sidewalls and bottom of the copper interconnection. On the top surface of the copper interconnects capping barrier layers are provided. Such capping barrier layers include various dielectric materials, e.g. silicon nitride (Si₃N₄).

A conventional BEOL interconnect utilizing copper metallization and cap layers described above includes a lower substrate which may contain logic circuit elements such as transistors, An inter-level dielectric (ILD) layer overlies the substrate. The ILD layer may be formed of, for example, silicon dioxide (SiO₂). However, in advanced interconnects, the ILD layer is preferably a tow-k polymeric thermoset material. An adhesion promoter layer may be disposed between the substrate and the ILD layer. A silicon nitride (Si₃N₄) layer is optionally disposed on the ILD layer. The silicon nitride layer is commonly known as a hardmask layer or polish stop layer. At least one conductor is embedded in the ILD layer. The conductor is typically copper in advanced interconnects, but alternatively may be aluminum or other conductive material. When the conductor is copper, a diffusion barrier liner is preferably disposed between the ILD layer and the copper conductor. The diffusion barrier liner is typically comprised of tantalum, titanium, tungsten, or nitrides of these metals.

The top surface of the conductor is made coplanar with the top surface of the hard mask nitride layer, usually by a chemical-mechanical polish (CMP) step. A cap layer, typically of silicon nitride, is disposed on the conductor and the hard mask nitride layer. The cap layer acts as a diffusion barrier to prevent diffusion of copper from the conductor into the surrounding dielectric material during subsequent processing steps. High density plasma (HOP) chemical vapor deposition (CVD) films such as silicon nitride provide superior electromigration protection, as compared to plasma enhanced (PE) CVD films, because HOP CVO films more readily stop the movement of copper atoms along the interconnect surface in the cap layer.

Recently, the use of ultra tow dielectric constant (ULK) dielectric materials (i e., k<3.0) for copper interconnects have turned to low-k two phase or polymeric thermoset dielectric materials. These dielectric materials require the use of post curing step using ultraviolet (UV) or electron beam (E-Beam) radiation. This post cure UV radiation, for example, causes increasing stress in the cap layer and causes cracking in both the cap layer and the ULK layers, Any crack in the cap layer may lead to copper diffusion into the ILD layer through the seam leading to formation of a copper nodule under the cap layer. Such a copper nodule may lead to short circuits due to leakage of current between adjacent interconnect lines, UV and/or E-beam radiation may also cause other damages such as increased stress, delamination and blister formation over patterned copper lines, particularly during subsequent dielectric depositions, metallization, and chemical-mechanical polishing.

In view of the foregoing, there is a need for a dielectric material with higher stability to UV and/or E-Beam radiation.

### SUMMARY OF THE INVENTION

A dielectric cap and related methods are disclosed. In one embodiment, the dielectric cap includes a dielectric material having an optical band gap (e.g., greater than about 3.0 electron-Volts) to substantially block ultraviolet radiation during a curing treatment, and including nitrogen with electron donor, double bond electrons. The dielectric cap exhibits a high modulus and is stable under post ULK UV curing treatments for, for example, copper low k backend-of-line (BEOL) nanoelectronic devices, leading to less film and device cracking and improved reliability.

A first aspect of the invention provides a dielectric cap comprising: a dielectric material having an optical band gap to substantially block ultraviolet radiation during a curing treatment, and including nitrogen with electron donor, double bond electrons.

A second aspect of the invention provides a method of forming a dielectric cap, the method comprising; providing an inter-level dielectric (ILD); forming a dielectric material layer over the ILD, the dielectric material having an optical band gap that substantially blocks ultraviolet radiation and includes nitrogen with electron donor, double bond electrons; and curing the dielectric material layer using the ultraviolet radiation.

A third aspect of the invention provides a dielectric cap comprising: silicon nitrogen based dielectric material having; a) an optical band gap greater than about 3.0 electron-Volts (eV) to substantially block ultraviolet radiation during a curing treatment; b) nitrogen with electron donor, double bond electrons; and c) a carbon constituent.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a dielectric cap according to embodiments of the invention.

FIG. 2 shows embodiments of a method of forming a dielectric cap.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

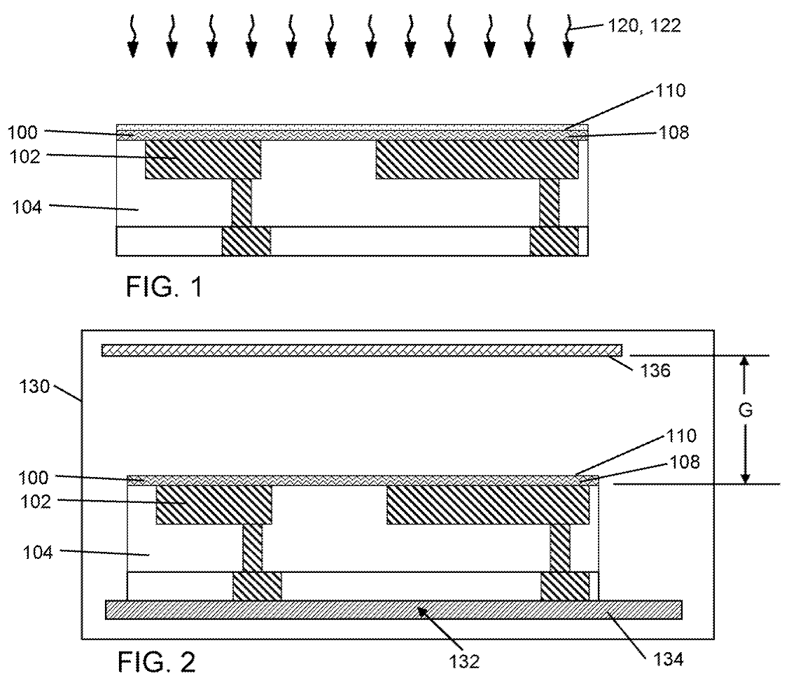

Referring to FIG. 1, a dielectric cap 100 and related methods are disclosed. Dielectric cap 100 is used in interconnect structures in ultra-large scale integrated (ULSI) nano and microelectronic integrated circuit (IC) chips including, for example, high speed microprocessors, application specific integrated circuits, memory storage devices, and related electronic structures with a multilayered barrier layer. Dielectric caps, in general, are very stable capping barrier layers used for, among other things, protecting interconnect-metallization in back-end-o-line (BEOL) structures under ultraviolet (UV) and/or E-beam radiation curing treatments.

Dielectric cap 100 may be formed, for example, over a conductor 102 such as copper (Cu) or aluminum (Al) in an inter-level dielectric (ILD) 104. ILD 104 may include any now known or later developed ultra low dielectric constant (ULK) material such as porous hydrogenated silicon oxycarbide (pSiCOH), spin-on low k dielectrics including p-SiCOH or organic and inorganic polymers. In one embodiment, dielectric cap 100 includes a dielectric material 108 having an optical band gap to substantially block ultraviolet radiation during a curing treatment, and includes nitrogen with electron donor, double bond electrons. Optical band gap as used herein refers to an energy level of light required to pass through a material. In one embodiment, dielectric material 108 has an optical band gap greater than about 3.0 electron-Volts (eV), i.e., ±0.5 eV. The optical band gap may be measured, for example, using optical exposure techniques. In one instance, optical band gap was measured using J. A. Woollam VUV-VASE equipment. The optical constant band gap data fits were a combination of Cauchy with an Urbach absorption tail, that resulted in very slight absorption in the 400-800 nm range. The depolarization levels were low (indicating idealized films) and common model improvements such as thickness non-uniformity and surface roughness do not improve model fits. The linear, Bruggman, and Maxwell-Garnet model options with Cauchy have also been used to obtain the band gap result, It is understood that the above optical band gap measuring techniques are meant to be illustrative and are not to be considered limiting.

It is emphasized that dielectric material according to embodiments of the invention may include any now known or later developed material capable of achieving the above-prescribed optical band gap and nitrogen with electron donor, double bond electrons, and otherwise function as a dielectric material. In embodiments of the invention, dielectric material 108 may include for example, silicon nitride (SiₓN_{y}) boron nitride (BNₓ), silicon boron nitride (SiBNₓ), silicon boron nitride carbon (SiBₓN_{y}C_{z}) and carbon boron nitride (CBₓN_{y}), where x and y values for each compound may vary depending on what proportions are necessary to attain the optical band gap and nitrogen with electron donor, double bond electrons. As indicated above, some embodiments of dielectric cap 100 may include a carbon (C) constituent, however, this is not always necessary. In those embodiments that contain carbon, it may be in the range of about 1% to about 40% by atomic composition of the material. In any event, any ionic bonding with ceramic properties material 108 with high optical band gap (i.e., >about 3.0 eV) and copper diffusion barrier properties (which usually means presence of suitable nitrogen bonding to form copper-nitrogen complexes to reduce diffusion) is considered within the scope of the invention

In one embodiment, dielectric material 108 comprises one of a strong silicon-nitrogen (SiN), nitrogen-silicon-carbon (NSiC) and silicon-carbon-nitrogen (SiCN) bonding matrix that prevents oxidation at an elevated temperature by forming an oxygen diffusion barrier 110 upon contact with oxygen (O₂) at the elevated temperature. In this case, oxygen diffusion barrier 110 may silicon-nitrogen-oxygen (SiNO), nitrogen-silicon-oxygen-carbon (NSiOC) or oxygen-silicon-nitrogen-carbon (OSiNCO) In these cases, oxygen (O2) constitutes about 1% to about 20% by atomic composition of the oxygen diffusion barrier 110. The elevated temperature may be greater than an integrated circuit (IC) chip maximum operating temperature in which the dielectric is used, e.g., greater than about 120° C. (±5° C.).

In another embodiment, dielectric material 108 comprises a tetrahedral bonding structure that prevents oxidation at an elevated temperature by forming an oxygen diffusion barrier 110 upon contact with oxygen (O₂) at the elevated temperature, Here again, oxygen diffusion barrier 110 may include: silicon-nitrogen-oxygen (SiNO), nitrogen-silicon-oxygen-carbon (NSiOC) or oxygen-silicon-nitrogen-carbon (OSiNC). Also, the elevated temperature may greater than an integrated circuit (IC) chip maximum operating temperature in which the dielectric is used, e.g., greater than about 120° C. (±5° C.).

In another embodiment, dielectric material 108 has a compressive stress of greater than about 200 MPa upon exposure to ultraviolet (UV) radiation 120 or E-beam radiation 122.

Dielectric cap 100 may be formed using any now known or later developed techniques to achieve the above-prescribed optical band gap and nitrogen with electron donor, double bond electrons. In embodiments of the invention, a method o forming dielectric cap 100 may be provided. An ILD 104 is provided in any now known or later developed manner, e.g., deposition. As mentioned above, ILD 104 may include any now known or later developed ultra low dielectric constant (ULK) material such as porous hydrogenated silicon oxycarbide (pSiCOH), spin-on low k dielectrics including p-SiCOH or organic and inorganic polymers. Conductor(s) 102 may be formed in ILD, e.g., using conventional Damascene processing.

As will be described in greater detail below, dielectric material 108 layer is formed over ILD 104, the dielectric material having an optical band gap that substantially blocks ultraviolet radiation and includes nitrogen with electron donor, double bond electrons. As noted above, the optical band gap may be, for example, greater than about 3.0 electron-Volts (eV). The particular processing used to form dielectric material 108 may vary depending on the material used. In one embodiment, dielectric material 108 includes silicon nitride (SiₓN_{y}) where x =1-3 and y=1-4. In this case, as shown in FIG. 2, the dielectric material 108 layer forming may include providing precursors in a parallel plate plasma enhanced chemical vapor deposition (PECVD) reactor 130. Parallel plate reactor 130 has a conductive area 132 of a substrate chuck 134 (i.e., lower electrode) between about 85 cm² and about 750 cm², and a gap G between substrate 140 and a top electrode 142 between about 1 cm and about 12 cm. When conductive area 132 of substrate chuck 134 is changed by a factor of X, the RF power applied to substrate chuck 134 is also changed by a factor of X. The precursors may include; a) a silicon-based precursor selected from the group consisting of: i) silane, ii) disilane and iii) a nitrogen containing silicon precursor comprising atoms of silicon (Si), nitrogen (N) and hydrogen (H) and an inert carrier selected from the group consisting of: helium (He) and argon (Ar), and b) a nitrogen containing precursor. Alternatively, aminosilane group materials either in gas or liquid phase may also be employed. One illustrative nitrogen containing precursor includes ammonia (NH₃); however, others exist such as nitrogen tri-flouride (NF₃), dihyrazine (N₂H₄) or nitrogen (N₂). A first radio frequency (RF) power is applied to one of electrodes 134, 142 at a frequency between about 0.45 MHz and about 200 MHz. First RF power density may be, for example, set at between about 0.1 W/cm² and about 5.0 W/cm² and between about 50 W and about 1000 W. Optionally, a second RF power of a lower frequency than the first RF power may be applied to one of electrodes 134, 142, e.g., set at between about 0.04 W/cm² and about 3 W/cm², and with a power of between about 20 W and about 600 W.

In one embodiment, a substrate temperature may be set at between about 100° C. and about 425° C. An inert carrier gas, e.g., helium (He) or argon (Ar), flow rate may be set at between about 10 standard cubic centimeters (sccm) to about 5000 sccm. Reactor 130 pressure may be set between about 100 mTorr and about 10,000 mTorr in which the pressure of 1000-1700 mTorr is the preferred range.

Curing dielectric material 108 layer using ultraviolet radiation 120 (FIG. 1) results in dielectric cap 100. During curing 120, however, only radiation having an energy level greater than about 3.0 eV will potentially pass through dielectric cap 100.

It is noted relative to the above-described embodiments that the conditions used for the deposition steps may vary depending on the desired final dielectric constant of dielectric cap 100.

The materials and methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A dielectric cap comprising:
a dielectric material having an optical band gap to substantially block ultraviolet radiation during a curing treatment, and including nitrogen with electron donor, double bond electrons.

2. The dielectric cap of claim 1, wherein the optical band gap is greater than about 3.0 electron-Volts (eV).

3. The dielectric cap of claim 1, wherein the dielectric material comprises one of a strong silicon-nitrogen (SiN), nitrogen-silicon-carbon (NSiC) and silicon-carbon-nitrogen (SiCN) bonding matrix that prevents oxidation at an elevated temperature by forming an oxygen diffusion barrier upon contact with oxygen (O₂) at the elevated temperature.

4. The dielectric cap of claim 3, wherein the oxygen diffusion barrier includes one of silicon-nitrogen-oxygen (SiNO), nitrogen-siliconoxygen-carbon (NSiOC) and oxygen-silicon-nitrogen-carbon (OSiNC).

5. The dielectric cap of claim 3, wherein the elevated temperature is greater than an integrated circuit (IC) chip maximum operating temperature in which the dielectric is used.

6. The dielectric cap of claim 5, wherein the elevated temperature is greater than about 120° C.

7. The dielectric cap of claim 1, wherein the dielectric material comprises a tetrahedral bonding structure that prevents oxidation at an elevated temperature by forming an oxygen diffusion barrier upon contact with oxygen (O₂) at the elevated temperature.

8. The dielectric cap of claim 7, wherein the oxygen diffusion barrier includes one of silicon-nitrogen-oxygen (SiNO) nitrogen-silicon-oxygen-carbon (NSiOC) and oxygen-silicon-nitrogen-carbon (OSiNC).

9. The dielectric cap of claim 7, wherein the elevated temperature is greater than an integrated circuit (IC) chip maximum operating temperature in which the dielectric cap is used.

10. The dielectric cap of claim 1, wherein the dielectric material is selected from the group consisting of: silicon nitride (SiₓN_{y}) boron nitride (BNₓ), silicon boron nitride (SiBNₓ) silicon boron nitride carbon (SiBₓN_{y}C_{z}) and carbon boron nitride (CBₓN_{y}).

11. The dielectric cap of claim 1, wherein the dielectric material has a compressive stress of greater than about 200 MPa upon exposure to one of ultraviolet (UV) radiation and E-beam radiation.

12. A method of forming a dielectric cap, the method comprising:
providing an inter-level dielectric (ILD);
forming a dielectric material layer over the ILD the dielectric material having an optical band gap that substantially blocks ultraviolet radiation and includes nitrogen with electron donor, double bond electrons; and
curing the dielectric material layer using the ultraviolet radiation.

13. The method of claim 12, wherein the optical band gap is greater than about 3.0 electron-Volts (eV).

14. The method of claim 12, wherein the dielectric material further comprises one of a strong silicon-nitrogen (SiN), nitrogen-silicon-carbon (NSiC) and silicon-carbon-nitrogen (SiCN) bonding matrix that prevents oxidation at an elevated temperature by forming an oxygen diffusion barrier upon contact with oxygen (O₂) at the elevated temperature.

15. The method of claim 14, wherein the oxygen diffusion barrier includes one of silicon-nitrogen-oxygen (SiNO), nitrogen-silicon-oxygen-carbon (NSiOC) and oxygen-silicon-nitrogen-carbon (OSiNC).

16. The method of claim 14, wherein the elevated temperature is greater than an integrated circuit (IC) chip maximum operating temperature in which the dielectric is used.

17. The method of claim 12, wherein the dielectric material further comprises a tetrahedral bonding structure that prevents oxidation at an elevated temperature by forming an oxygen diffusion barrier upon contact with oxygen (O₂) at the elevated temperature.

18. The method of claim 17, wherein the oxygen diffusion barrier includes one of: silicon-nitrogen-oxygen (SiNO), nitrogen-silicon-oxygen-carbon (NSiOC) and oxygen-silicon-nitrogen-carbon (OSiNC).

19. The method of claim 17, wherein the elevated temperature is greater than an integrated circuit (IC) chip maximum operating temperature in which the dielectric is used.

20. The method of claim 12, wherein the dielectric material is selected from the group consisting of: silicon nitride (SiₓN_{y}), boron nitride (BNₓ), silicon boron nitride (SiBNₓ), silicon boron nitride carbon (SiBₓN_{y}C_{z}) and carbon boron nitride (CBₓN_{y}).

21. The method of claim 12, wherein the dielectric material layer includes silicon nitride (SiₓN_{y}), and the dielectric material layer forming includes;
providing a precursor in a parallel plate plasma enhanced chemical vapor deposition (PECVD) reactor,
the parallel plate reactor having a conductive area of a substrate chuck between about 85 cm² and about 750 cm², and a gap between the substrate and a top electrode between about 1 cm and about 12 cm,
the precursor including:
a) a silicon-based precursor selected from the group consisting of: i) silane, ii) disilane and iii) a nitrogen containing silicon precursor comprising atoms of silicon (Si), nitrogen (N) and hydrogen (H) and an inert carrier selected from the group consisting of; helium (He) and argon (Ar), and
b) a nitrogen containing precursor, and
applying a first radio frequency (RF) power to one of the electrodes at a frequency between about 0.45 MHz and about 200 MHz.

22. The method of claim 21, wherein the nitrogen containing precursor is selected from the group consisting of: ammonia (NH₃), nitrogen trifluoride (NF₃), dihyrazine (N₂H₄) and nitrogen (N₂).

23. The method of claim 21 wherein the applying includes applying a second RF power of a lower frequency than the first RE power to one of the electrodes.

24. The method of claim 21, wherein the dielectric material layer forming further includes:
setting a substrate temperature at between about 100° C. and about 425° C.;
setting the first RF power density at between about 0.1 W/Cm² and about 5.0 W/cm²;
setting an inert carrier gas flow rate at between about 10 sccm to about 5000 sccm;
setting a reactor pressure at a pressure between about 100 mTorr and about 10,000 mTorr; and
setting the first RF power between about 50 W and about 1000 W.

25. The method of claim 24, further comprising applying the second RF power between about 20 W and about 600 W.

26. The method of claim 12, wherein the dielectric material has a compressive stress of greater than about 200 MPa after the curing.

27. A dielectric cap comprising:
silicon nitrogen based dielectric material having: a) an optical band gap greater than about 3.0 electron-Volts (eV) to substantially block ultraviolet radiation during a curing treatment; b) nitrogen with electron donor, double bond electrons; and c) a carbon constituent.

28. The dielectric of claim 27, wherein the silicon nitrogen based dielectric material further comprises one of a strong nitrogen-silicon-carbon (NSiC) and siliconcarbon-nitrogen (SiCN) bonding matrix that prevents oxidation at an elevated temperature by forming an oxygen diffusion barrier upon contact with oxygen (O₂) at the elevated temperature, and the oxygen diffusion barrier includes one of: silicon-nitrogen-oxygen (SiNO), nitrogen-silicon-oxygen-carbon (NSiOC) and oxygen-silicon-nitrogen-carbon (OSiNC).

29. The dielectric of claim 27, wherein the silicon nitrogen based dielectric material further comprises a tetrahedral bonding structure that prevents oxidation at an elevated temperature by forming an oxygen diffusion barrier upon contact with oxygen (O₂) at the elevated temperature, and the oxygen diffusion barrier includes one of: silicon-nitrogen-oxygen (SiNO), nitrogen-silicon-oxygen-carbon (NSiOC) and oxygen-silicon-nitrogen-carbon (OSiNC).

30. The dielectric of claim 27, wherein the silicon nitrogen based dielectric material has a compressive stress of greater than about 200 MPa upon exposure to one of ultraviolet (UV) radiation and E-beam radiation.
